(19) United States
(12) Patent Application Publication
(10) Pub. No.: US 2026/0156982 A1
(43) Pub. Date: Jun. 4, 2026

(54) LIGHT-EMITTING SUBSTRATE AND DISPLAY APPARATUS

(71) Applicants: Beijing BOE Technology Development Co., Ltd., Beijing (CN); BOE Technology Group Co., Ltd., Beijing (CN)

(72) Inventors: Meirong LU, Beijing (CN); Chunfang ZHANG, Beijing (CN); Weixing LIU, Beijing (CN); Jintao PENG, Beijing (CN); Kai GUO, Beijing (CN); Zhiqiang XU, Beijing (CN); Wanpeng TENG, Beijing (CN); Shulei LI, Beijing (CN); Zhikun GAO, Beijing (CN); Bin QIN, Beijing (CN); Jinyu REN, Beijing (CN)

(21) Appl. No.: 18/715,032

(22) PCT Filed: Aug. 29, 2023
(86) PCT No.: PCT/CN2023/115462

§ 371 Date: May 30, 2024

(51) Int. Cl. H10H 20/851; H10H 20/856

(52) U.S. Cl. CPC H10H 20/8514; H10H 20/856

(57) ABSTRACT

The present disclosure provides a light-emitting substrate and a display apparatus, and belongs to the field of display technology. The light-emitting substrate of the present disclosure includes: a dielectric substrate having a plurality of first grooves; a plurality of light-emitting chips on the dielectric substrate; and a color conversion layer including a plurality of color conversion patterns on an emission side of the light-emitting chips; where at least one of the color conversion patterns is in the first grooves.

### TECHNICAL FIELD

The present disclosure relates to the field of display technology, and specifically relates to a light-emitting substrate and a display apparatus.

### BACKGROUND

Since liquid crystal itself does not emit light, display is implemented through an external light source, in various liquid crystal display devices such as liquid crystal monitors, liquid crystal televisions and the like. Currently, the liquid crystal display (LCD) has gradually become the mainstream of flat panel displays. LCDs are classified into reflective LCDs and transmissive LCDs. The reflective LCD relies on ambient light from the outside, while the transmissive LCD relies on a backlight structure. Therefore, a thickness of the backlight structure directly determines a thickness of the liquid crystal display, and to obtain an ultra-thin display device, the thickness of the backlight structure has to be reduced. Therefore, an urgent technical problem to be solved is how to provide a lighter and thinner backlight structure.

### SUMMARY

To solve at least one of the problems in the existing art, the present disclosure provides a light-emitting substrate and a display apparatus.

An embodiment of the present disclosure provides a light-emitting substrate, including
a dielectric substrate having a plurality of first grooves;
a plurality of light-emitting chips on the dielectric substrate; and
a color conversion layer including a plurality of color conversion patterns on an emission side of the light-emitting chips; wherein at least one of the color conversion patterns is in the first grooves.

In some examples, the light-emitting substrate further includes a first microstructure on a side of the light-emitting chips close to the color conversion patterns, wherein a certain distance is provided between the first microstructure and the dielectric substrate, and the first microstructure is configured to gather light emitted from the light-emitting chips and transmit the gathered light to the color conversion patterns.

In some examples, the light-emitting substrate further includes a first microstructure on the dielectric substrate and on a side of the color conversion patterns close to the light-emitting chips, wherein a certain distance is provided between the first microstructure and the light-emitting chips, and the first microstructure is configured to gather light emitted from the light-emitting chips and transmit the gathered light to the color conversion patterns.

In some examples, the dielectric substrate has a plurality of second grooves, each of which is provided with one lens assembly of the first microstructure.

In some examples, each of the color conversion patterns includes a plurality of color conversion units arranged at intervals; each of the first grooves includes a plurality of first sub-grooves arranged at intervals and each provided with one of the color conversion units; and lens assemblies of each of the first microstructures are in one-to-one correspondence with the color conversion units.

In some examples, the color conversion layer includes a plurality of color conversion sublayers and a plurality of transparent film layers alternately arranged in a stack; and light emitted from the light-emitting chips is transmitted and reflected at interfaces of the color conversion sublayers and the transparent film layers.

In some examples, the light-emitting substrate further includes a transflective film layer on a side of the color conversion patterns away from the light-emitting chips, wherein the transflective film layer is configured to transmit a part and reflect another part of light emitted from the light-emitting chips.

In some examples, the light-emitting chips are configured to emit light of a first color which excites the color conversion layer to emit light of a second color and light of a third color; the light-emitting substrate further includes a distributed Bragg reflector on a side of the color conversion layer away from the light-emitting chips; the distributed Bragg reflector has a reflectivity to the light of the second color and a reflectivity to the light of the third color each lower than a reflectivity to the light of the first color; and the distributed Bragg reflector has a transmittance to the light of the second color and a transmittance to the light of the third color each higher than a transmittance to the light of the first color.

In some examples, the distributed Bragg reflector includes titanium dioxide film layers and zinc oxide film layers sequentially and alternately arranged in a direction away from the color conversion patterns; or, the distributed Bragg reflector includes zinc oxide film layers and silicon dioxide film layers sequentially and alternately arranged in a direction away from the color conversion patterns.

In some examples, the dielectric substrate has a first surface facing the light-emitting chips and having a flat region and a groove region; the first grooves are in the groove region; the flat region of the first surface is a rough surface provided with a first reflective layer on a side close to the light-emitting chips.

In some examples, the dielectric substrate has a first surface facing the light-emitting chips; the light-emitting substrate further includes: a second microstructure and a light-shielding layer on the first surface and sequentially arranged in a direction approaching the light-emitting chips; the second microstructure is configured to diffuse light emitted from the color conversion layer; and the light-emitting substrate further includes first openings running through the second microstructure and the light-shielding layer, through which light emitted from the light-emitting chips impinges onto the color conversion patterns.

In some examples, in a plane where the dielectric substrate is located, an orthographic projection of each of the first grooves covers an orthographic projection of one of the first openings.

In some examples, the light-emitting substrate further includes a first lead terminal and a second lead terminal on the dielectric substrate and at two opposite sides of each of the first grooves; wherein a first connection pad of each of the light-emitting chips is connected to the first lead terminal, and a second connection pad of each of the light-emitting chips is connected to the second lead terminal.

In some examples, the first connection pad is disposed toward, and directly connected to, the first lead terminal; and the second connection pad is disposed toward, and directly connected to, the second lead terminal.

In some examples, the first connection pad is disposed away from the first lead terminal, and connected to the first lead terminal by a first signal line; and the second connection pad is disposed away from the second lead terminal, and connected to the second lead terminal by a second signal line.

In some examples, the light-emitting substrate further includes a scattering layer on a side of the color conversion patterns away from the light-emitting chips.

In some examples, the light-emitting substrate further includes a package layer that covers the color conversion layer.

In some examples, the light-emitting substrate further includes a second reflective layer on a side of the light-emitting chips away from the dielectric substrate.

In some examples, the color conversion layer is made of a material including quantum dots or phosphors.

An embodiment of the present disclosure provides a display apparatus, including any light-emitting substrate as described above.

### BRIEF DESCRIPTION OF DRAWINGS

FIG. 1 is a sectional view of an exemplary light-emitting chip.

FIG. 2 is a sectional view of a backlight structure according to an embodiment of the present disclosure.

FIG. 3 is a sectional view of a first exemplary backlight structure according to an embodiment of the present disclosure.

FIG. 4 is a sectional view of a second exemplary backlight structure according to an embodiment of the present disclosure.

FIG. 5 is a sectional view of a third exemplary backlight structure according to an embodiment of the present disclosure.

FIG. 6 is a sectional view of a color conversion layer and a transparent film layer in the backlight structure in FIG. 5.

FIG. 7 is a sectional view of a fourth exemplary backlight structure according to an embodiment of the present disclosure.

FIG. 8 is a sectional view of a fifth exemplary backlight structure according to an embodiment of the present disclosure.

FIG. 9 is a sectional view of a distributed Bragg reflector in the backlight structure in FIG. 8.

FIG. 10 is a reflectivity vs. wavelength plot for the distributed Bragg reflector structure in FIG. 9.

FIG. 11 is a sectional view of another distributed Bragg reflector in the backlight structure in FIG. 8.

FIG. 12 is a reflectivity vs. wavelength plot for the distributed Bragg reflector structure in FIG. 11.

FIG. 13 is a sectional view of a sixth exemplary backlight structure according to an embodiment of the present disclosure.

FIG. 14 is a top view of a color conversion layer in the backlight structure in FIG. 13.

FIG. 15 is a schematic diagram showing refraction angles of light by a lens assembly and a dielectric substrate in the backlight structure in FIG. 13.

FIG. 16 is a flowchart illustrating a process of forming a first microstructure on the dielectric substrate in the backlight structure in FIG. 13.

FIG. 17 is a sectional view of a seventh exemplary backlight structure according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Also, the terms “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

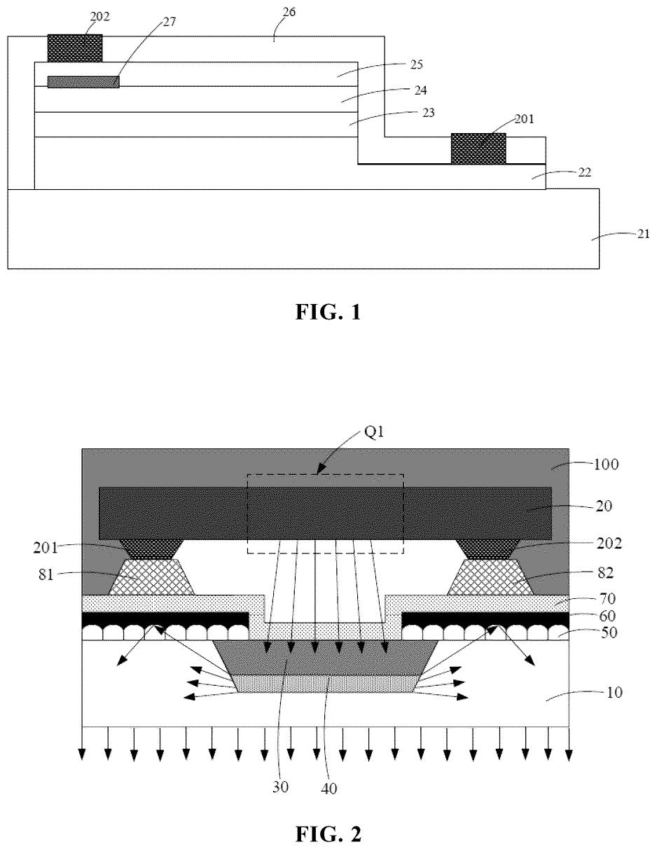

FIG. 1 is a sectional view of an exemplary light-emitting chip. As shown in FIG. 1, the light-emitting chip may be specifically an LED chip including a transparent substrate 21 and a semiconductor stacked structure on the transparent substrate 21.

The transparent substrate 21 may include sapphire, but is not limited thereto, and in addition to an insulation substrate, the transparent substrate 21 may be a conductive substrate or semiconductor substrate that can ensure light transmission characteristics. A concave-convex structure (not shown) may be formed on an upper surface of the transparent substrate 21. The concave-convex structure can increase the light extraction efficiency and improve the growth quality of single crystals.

The semiconductor stacked structure may include a first semiconductor layer 22, an active layer 23, and a second semiconductor layer 24. The first semiconductor layer may be an n-type nitride semiconductor layer including a composition of InₓAl_{y}Ga_{1-x-y}N (0≤x<1, 0≤y<1, and 0≤(x+y)<1), where the n-type impurity may be silicon. For example, the first semiconductor layer 21 may include n-type GaN. The second semiconductor layer 24 may be a p-type nitride semiconductor layer including a composition of InₓAl_{y}Ga_{1-x-y}N (0≤x<1, 0≤y<1, and 0≤(x+y)<1), where the p-type impurity may be magnesium. For example, the second semiconductor layer 24 may have a single layer structure, but may have a multi-layer structure of different compositions in some exemplary embodiments. The active layer 23 may have a multiple quantum well (MQW) structure in which quantum well layers and quantum barrier layers are alternately stacked on each other. For example, the quantum well layer and the quantum barrier layer may include different compositions of InₓAl_{y}Ga_{1-x-y}N (0≤x≤1, 0≤y≤1, and 0≤(x+y)≤1), respectively. In some examples, the quantum well layer may include a composition of InₓGa₁₋ₓN (0<x≤1), while the quantum barrier layer may include GaN or AlGaN. The active layer 23 is not limited to the MQW structure, and may have a single quantum well (SQW) structure.

In some examples, a buffer layer (not shown) may be provided between the transparent substrate 21 and the first semiconductor layer 22, and the buffer layer may have a composition of InₓAl_{y}Ga_{1-x-y}N (0≤x≤1, and 0≤y≤1). For example, the buffer layer may include GaN, AlN, AlGaN, or InGaN. The buffer layer may be formed by combining a plurality of layers or gradually changing compositions thereof, if necessary.

In some examples, the LED chip includes a first electrode and a second electrode 25, which may be disposed on a mesa-etched region of the first semiconductor layer 22 and on the second semiconductor layer 24, respectively, so that the first electrode and the second electrode 25 can be located on the same side of the LED chip. For example, the first electrode may include at least one of Al, Au, Cr, Ni, Ti, or Sn. The second electrode may include a reflective metal. For example, the second electrode 25 may include a material such as Ag, Ni, Al, Cr, Rh, Pd, Ir, Ru, Mg, Zn, Pt, or Au, and may be used as a structure having a single layer or two or more layers.

In some examples, as shown in FIG. 1, the light-emitting chip may be provided with only the second electrode 25 without the first electrode, and the second electrode is a transparent electrode. For example, the second electrode 25 is made of a transparent conductive material such as ITO. In this case, an insulation layer 26 is disposed on a side of the second electrode 25 away from the second semiconductor layer 24, a first connection pad 201 is disposed in the mesa-etched region of the first semiconductor layer 22 through a via running through the insulation layer 26, a second connection pad 202 is disposed on the second electrode 25 through a via running through the insulation layer 26, and the first connection pad 201 and the second connection pad 202 may be located on the same side of the LED chip. Further, a current blocking layer 27 may be provided between the second electrode 25 and the second semiconductor layer 24. In the embodiments of the present disclosure, only the light-emitting chip having such a structure is described as an example.

An embodiment of the present disclosure provides a light-emitting substrate adopting the LED chip as described above. The light-emitting substrate includes, but is not limited to, a backlight structure, and in the embodiments of the present disclosure, only the light-emitting substrate being a backlight structure is taken as an example for description. The LED chip may be a blue LED chip, or alternatively, a green LED chip or a red LED chip, or an LED chip of more than one colors of blue, green and red. In the embodiments of the present disclosure, only the LED chip being a blue LED chip is taken as an example.

It should be further noted that where the LED chip in the embodiments of the present disclosure is a blue LED chip, a color conversion layer may be composed of a red color conversion material and a green color conversion material. For example: the color conversion layer is made of a material including quantum dots or phosphors. Where the color conversion layer is made of quantum dots, the material of the color conversion layer may specifically include red quantum dots and green quantum dots, and in this case, blue light emitted from the blue light LED chip can excite the red quantum dots to emit red light, and excite the green quantum dots to emit green light. Where the color conversion layer is made of phosphors, the material of the color conversion layer may specifically include red phosphors and green phosphors, and in this case, blue light emitted from the blue light LED chip can excite the red phosphors to emit red light, and excite the green phosphors to emit green light. In other words, as used in the embodiments of the present disclosure, the first color is blue, the second color is green, and the third color is red.

Next, a backlight structure provided in the embodiments of the present disclosure is specifically described.

FIG. 2 is a sectional view of a backlight structure according to an embodiment of the present disclosure. As shown in FIG. 2, an embodiment of the present disclosure provides a backlight structure, including a dielectric substrate 10, a plurality of LED chips 20, and a color conversion layer on an emission surface side of the LED chips 20. The dielectric substrate 10 in the embodiment of the present disclosure has a plurality of first grooves, and the color conversion layer includes a plurality of color conversion patterns 30. At least one of the color conversion patterns 30 is located in the first grooves.

It should be noted that in the embodiments of the present disclosure, only the case where the color conversion patterns 30 and the first grooves are provided in one-to-one correspondence, and one color conversion pattern 30 is disposed in one first groove and corresponds to one LED chip is taken as an example for illustration.

In the backlight structure provided in the embodiments of the present disclosure, by providing the first grooves in the dielectric substrate 10, and placing the color conversion patterns 30 in the first grooves, a thickness of the backlight structure can be significantly reduced, thereby obtaining a lighter and thinner backlight structure.

In some examples, the dielectric substrate 10 includes, but is not limited to, a glass substrate, and in the embodiments of the present disclosure, only the dielectric substrate 10 being a glass substrate is taken as an example for illustration.

In some examples, with continued reference to FIG. 2, in addition to the above structures, the backlight structure in the embodiments of the present disclosure may further include a scattering layer 40 on a side of the color conversion pattern 30 away from the LED chip 20. The scattering layer 40 may be provided in the first groove and located between a bottom of the first groove and the color conversion pattern 30; and the scattering layer 40 is configured to scatter light emitted from the LED chip 20 and re-emitted through the color conversion pattern 30. It should be noted that the light emitted through the color conversion pattern 30 includes not only light emitted from a color conversion material in the color conversion pattern 30 activated by light emitted from the LED chip 20, but also a part of light directly emitted from the LED chip 20. In other words, the light emitted through the color conversion pattern 30 includes three colors, i.e., red, green and blue.

Further, with continued reference to FIG. 2, the dielectric substrate 10 has a first surface facing the LED chip 20; and in addition to the above structures, the backlight structure further includes: a second microstructure 50 and a light-shielding layer 60 on the first surface and sequentially arranged in a direction approaching the LED chip 20. The second microstructure 50 is configured to diffuse the light emitted from the color conversion layer; and the backlight structure includes a first opening running through the second microstructure 50 and the light-shielding layer 60, through which light emitted from the LED chip 20 impinges onto the color conversion pattern 30. The first opening may be disposed in one-to-one correspondence with the LED chip 20, and in this case, light scattered by the scattering layer 40 impinges onto the second microstructure 50 and then is further diffused, so that the light is more uniform, and by providing the light-shielding layer 60, light leakage can be effectively prevented.

Further, the second microstructure 50 may specifically adopt a lens structure, which is equivalent to a diffusion plate. The light-shielding layer 60 may be made of a black resin material or a light-shielding metal material, which is not particularly limited in the embodiments of the present disclosure.

Furthermore, in a plane where the dielectric substrate 10 is located, an orthographic projection of one of the first grooves covers an orthographic projection of one of the first openings. In other words, a size of the first opening is smaller than a maximum caliber of the first groove, that is, an opening edge of the first groove is covered by the second microstructure 50 and the light-shielding layer 60, thereby effectively preventing light leakage.

Further, with continued reference to FIG. 2, a package layer 70 is provided on a side of the light-shielding layer 60 away from the dielectric substrate 10, and covers at least the color conversion layer, to prevent the color conversion layer from being corroded by external water and oxygen. Specifically, the package layer 70 may be formed on a side of the light-shielding layer 60 away from the second microstructure 50, and has a planar structure which can better seal the structures on the dielectric substrate 10.

In some examples, with continued reference to FIG. 2, the side of the LED chip 20 away from the dielectric substrate 10 is covered with a second reflective layer 100, to cause light emitted from the LED chip 20 to exit towards the dielectric substrate 10. In some examples, the second reflective layer 100 includes, but is not limited to, white oil.

In some examples, with continued reference to FIG. 2, the LED chip 20 is a flip chip, i.e., the first connection pad 201 and the second connection pad 202 of the LED chip 20 are arranged towards the dielectric substrate 10. Accordingly, the backlight structure includes a first lead terminal 81 and a second lead terminal 82 on the dielectric substrate 10 and at two opposite sides of the first groove. The first connection pad 201 of the LED chip 20 is connected to the first lead terminal 81, and the second connection pad 202 of the LED chip 20 is connected to the second lead terminal 82. Specifically, the first connection pad 201 and the first lead terminal 81 may be connected by soldering, and similarly, the second connection pad 202 and the second lead terminal 82 may also be connected by soldering.

Alternatively, the LED chip 20 may be a face up chip, that is, the first connection pad 201 and the second connection pad 202 of the LED chip 20 are disposed away from the dielectric substrate 10. Accordingly, the first connection pad 201 may be connected to the first lead terminal 81 on the dielectric substrate 10 through a first signal line 101, and the second connection pad 202 may be connected to the second lead terminal 82 on the dielectric substrate 10 through a second signal line 102. In this example, the face up LED chip 20 can further reduce a distance between the emission surface of the LED chip 20 and the color conversion pattern 30, reduce a transmission distance of the light emitted from the LED chip 20 in the air medium, and increase the utilization rate of the light.

The backlight structure in the embodiments of the present disclosure is described below with reference to specific examples.

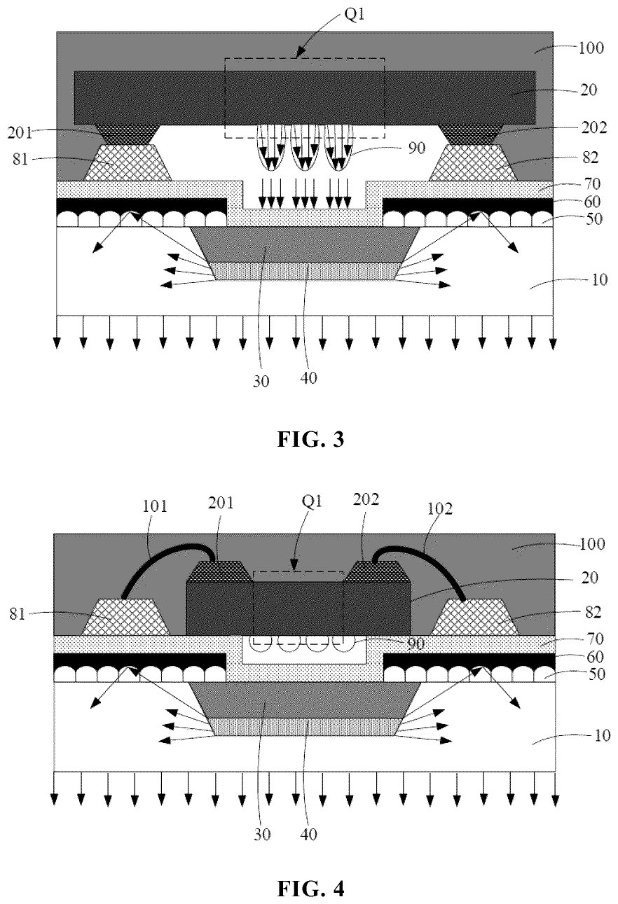

First example: FIG. 3 is a sectional view of a first exemplary backlight structure according to an embodiment of the present disclosure. As shown in FIG. 3, the backlight structure includes a dielectric substrate 10, an LED chip 20, a color conversion layer, and a first microstructure 90. The first microstructure 90 is located between the LED chip 20 and the color conversion layer. The dielectric substrate 10 has a plurality of first grooves each receiving one color conversion pattern 30. The first microstructure 90 is disposed over an emission region Q1 of the LED chip 20, has a certain distance from the dielectric substrate 10, and can gather light emitted from the LED chip 20 and transmit the gathered light to the color conversion pattern 30.

Specifically, in the backlight structure provided in the embodiments of the present disclosure, the first microstructure 90 is provided on an emission surface side of the LED chip 20 to gather the light emitted from the LED chip 20, so that the light emitted from the LED chip 20 is no longer in a scattering state, and then the light gathered by the first microstructure 90 is collimated and impinges to the color conversion pattern 30. In this case, the first microstructure 90 on the emission surface side the LED chip 20 can reduce a transmission distance of the light emitted from the LED chip 20 in the air medium, effectively solve the problem of light loss caused by a large distance between the LED chip 20 and the color conversion pattern 30, and increase the utilization rate of light. In addition, after passing through the first microstructure 90, the light emitted from the LED chip 20 is collimated and impinges to the color conversion pattern 30, so that the reflected light entering the color conversion pattern 30 can be reduced.

In some examples, the first microstructure 90 may be a lens array composed of a plurality of lens assemblies 901 arranged in an array.

In some examples, with continued reference to FIG. 3, in addition to the above structures, each backlight structure in the embodiment of the present disclosure may further include a scattering layer 40 on a side of the color conversion pattern 30 away from the LED chip 20. The scattering layer 40 may be provided in the first groove and located between a bottom of the first groove and the color conversion pattern 30; and the scattering layer 40 is configured to scatter light re-emitted through the color conversion pattern 30. Further, with continued reference to FIG. 3, the dielectric substrate 10 has a first surface facing the LED chip 20; and in addition to the above structures, the backlight structure further includes: a second microstructure 50 and a light-shielding layer 60 on the first surface and sequentially arranged in a direction approaching the LED chip 20. The second microstructure 50 is configured to diffuse the light emitted from the color conversion layer; and the backlight structure includes a first opening running through the second microstructure 50 and the light-shielding layer 60, through which light emitted from the LED chip 20 impinges onto the color conversion pattern 30. In this case, light scattered by the scattering layer 40 impinges onto the second microstructure 50 and then is further diffused, so that the light is more uniform, and by providing the light-shielding layer 60, light leakage can be effectively prevented.

Further, the second microstructure 50 may specifically adopt a lens structure, which is equivalent to a diffusion plate. The light-shielding layer 60 may be made of a black resin material or a light-shielding metal material, which is not particularly limited in the embodiments of the present disclosure.

Furthermore, in a plane where the dielectric substrate 10 is located, an orthographic projection of one of the first grooves covers an orthographic projection of one of the first openings. In other words, a size of the first opening is smaller than a maximum caliber of the first groove, that is, an opening edge of the first groove is covered by the second microstructure 50 and the light-shielding layer 60, thereby effectively preventing light leakage.

Further, with continued reference to FIG. 3, a package layer 70 is provided on a side of the light-shielding layer 60 away from the dielectric substrate 10, and covers at least the color conversion layer, to prevent the color conversion layer from being corroded by external water and oxygen. Specifically, the package layer 70 may be formed on a side of the light-shielding layer 60 away from the second microstructure 50, and has a planar structure which can better seal the structures on the dielectric substrate 10.

In some examples, with continued reference to FIG. 3, the side of the LED chip 20 away from the dielectric substrate 10 is covered with a second reflective layer 100, to cause light emitted from the LED chip 20 to exit towards the dielectric substrate 10. In some examples, the second reflective layer 100 includes, but is not limited to, white oil.

In some examples, with continued reference to FIG. 3, the LED chip 20 is a flip chip, i.e., the first connection pad 201 and the second connection pad 202 of the LED chip 20 are arranged towards the dielectric substrate 10. Accordingly, the backlight structure includes a first lead terminal 81 and a second lead terminal 82 on the dielectric substrate 10 and at two opposite sides of the first groove. The first connection pad 201 of the LED chip 20 is connected to the first lead terminal 81, and the second connection pad 202 of the LED chip 20 is connected to the second lead terminal 82. Specifically, the first connection pad 201 and the first lead terminal 81 may be connected by soldering, and similarly, the second connection pad 202 and the second lead terminal 82 may also be connected by soldering.

Second example: FIG. 4 is a sectional view of a second exemplary backlight structure according to an embodiment of the present disclosure. As shown in FIG. 4, this backlight structure is substantially the same as that of the first example, except that the LED chip 20 in this example is a face up chip, that is, the first connection pad 201 and the second connection pad 202 of the LED chip 20 are disposed away from the dielectric substrate 10. Accordingly, the first connection pad 201 may be connected to the first lead terminal 81 on the dielectric substrate 10 through a first signal line 101, and the second connection pad 202 may be connected to the second lead terminal 82 on the dielectric substrate 10 through a second signal line 102. In this example, the face up LED chip 20 can further reduce a distance between the emission surface of the LED chip 20 and the color conversion pattern 30, reduce a transmission distance of the light emitted from the LED chip 20 in the air medium, and increase the utilization rate of the light.

In some examples, two ends of the first signal line 101 may be connected to the first connection pad 201 and the first lead terminal 81 by soldering, respectively; and similarly, two ends of the second signal line 102 may be connected to the second connection pad 202 and the second lead terminal 82 by soldering, respectively. Alternatively, the first signal line 101 and the second signal line 102 may be formed by depositing metals, in which case, two ends of the first signal line 101 are directly connected to the first connection pad 201 and the first lead terminal 81, respectively, and two ends of the second signal line 102 are directly connected to the second connection pad 202 and the second lead terminal 82, respectively.

Other structures in this example may be the same as those in the first example, and thus are not repeated here.

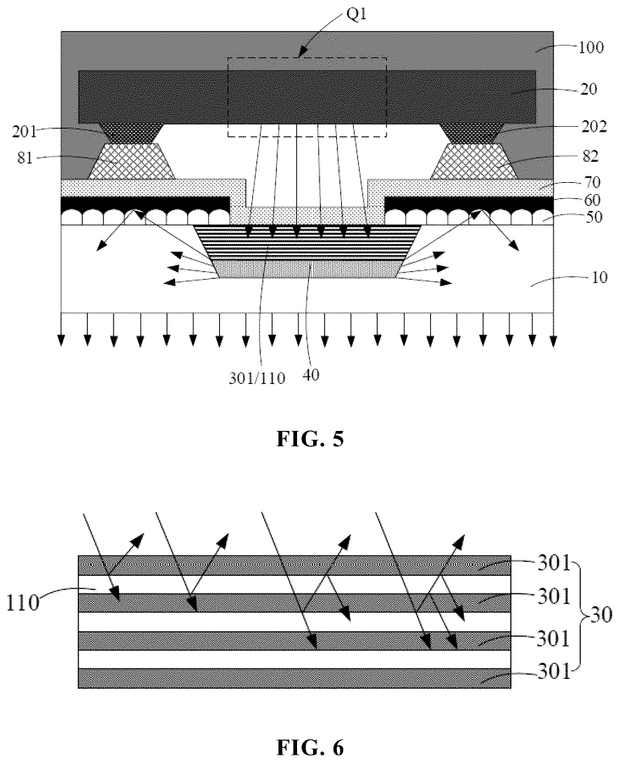

Third example: FIG. 5 is a sectional view of a third exemplary backlight structure according to an embodiment of the present disclosure. FIG. 6 is a sectional view of a color conversion pattern and a transparent film layer in the backlight structure in FIG. 5. As shown in FIGS. 5 and 6, this backlight structure is substantially the same as that of the first example, except that the color conversion pattern 30 in this example includes a plurality of color conversion sublayers 301 and a plurality of transparent film layers 110. The color conversion sublayers 301 and the transparent film layers 110 are stacked and alternately arranged, in which case, light emitted from the LED chip 20 is transmitted and reflected at interfaces of the color conversion sublayers 301 and the transparent film layers 110. In other words, the light emitted from the LED chip 20 is transmitted and reflected at upper and lower interfaces of the transparent film layer 110.

Specifically, taking the case where the LED chip 20 emits blue light (i.e., a blue LED chip 20), and the color conversion pattern 30 includes a red color conversion material and a green color conversion material as an example, since the color conversion pattern 30 has a relatively low conversion efficiency in the conventional backlight structure, the blue light will have a greater emission rate than the red/green light. Referring to FIG. 6, in this example, by alternately arranging the color conversion sublayers 301 and the transparent film layers 110, a part of the blue light emitted from the LED chip 20 and transmitted at the upper and lower interfaces of the transparent film layer 110 will excite the color conversion sublayer 301 to convert the light into red light and green light while a part of the reflected light is further transmitted and reflected between the film layers, and excite the color conversion sublayer 301 to convert the light into red light and green light, thereby increasing the color conversion efficiency and alleviating the problem of emitting bluish light from the backlight.

In some examples, each transparent film layer 110 is disposed between any two adjacent color conversion sublayers 301 of the color conversion pattern 30. The light emitted from the LED chip 20 is transmitted and reflected at the upper and lower interfaces of the transparent film layer 110, so as to increase an optical path of the light emitted from the LED chip 20 and thereby increase the color conversion efficiency.

Other structures in this example may be the same as those in the first example, and thus are not repeated here.

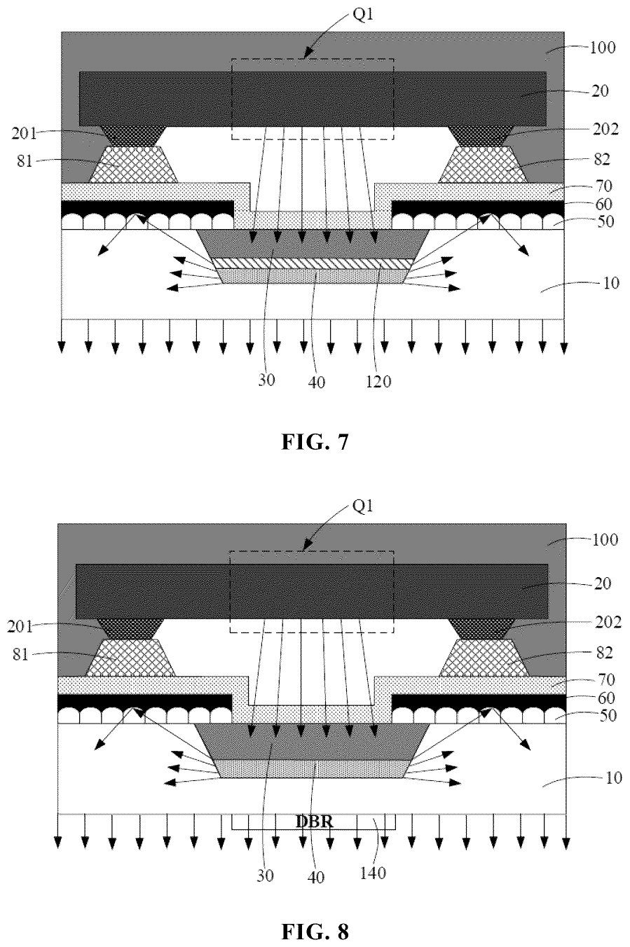

Fourth example: FIG. 7 is a sectional view of a fourth exemplary backlight structure according to an embodiment of the present disclosure. As shown in FIG. 7, this backlight structure is substantially the same as that of the first example, except that a transflective film layer is disposed on a side of the color conversion pattern 30 of the backlight structure away from the light-emitting chip, and the transflective film layer 120 is configured to transmit a part and reflect another part of the light emitted from the LED chip 20.

The case where the LED chip 20 emits blue light (i.e., a blue LED chip 20), and the color conversion pattern 30 includes a red color conversion material and a green color conversion material is taken as an example. Since the color conversion pattern 30 has a relatively low conversion efficiency in the conventional backlight structure, the blue light will have a greater emission rate than the red/green light. In this example, the transflective film layer 120 is provided to transmit a part and reflect another part of the light emitted from the LED chip 20, while the reflected light can further excite the color conversion pattern 30 to convert the light into red and green light, thereby increasing the color conversion efficiency of the color conversion pattern 30, and alleviating the problem of emitting bluish light from the backlight.

In some examples, where a scattering layer 40 is provided in the backlight structure, the transflective film layer 120 may be specifically disposed between the color conversion pattern 30 and the scattering layer 40. In this case, the light may be scattered and emitted from the scattering layer 40 after being sufficiently converted.

Other structures in this example may be the same as those in the first example, and thus are not repeated here.

Fifth example: FIG. 8 is a sectional view of a fifth exemplary backlight structure according to an embodiment of the present disclosure. As shown in FIG. 8, this backlight structure is substantially the same as that of the first example, except that the backlight structure further includes a distributed Bragg reflector (DBR) 140 on a side of the color conversion pattern 30 away from the light-emitting chip. The case where the LED chip 20 emits blue light, and the color conversion pattern 30 includes a red color conversion material and a green color conversion material is taken as an example. The distributed Bragg reflector 140 has a reflectivity to red light and a reflectivity to green light each lower than a reflectivity to blue light; and the distributed Bragg reflector 140 has a transmittance to red light and a transmittance to green light each higher than a transmittance to blue light. In other words, the distributed Bragg reflector 140 has a higher reflectivity for blue light and high transmittances for red and green light. In this example, blue light is highly reflected by the distributed Bragg reflector 140, so that the reflected blue light can further excite the color conversion pattern 30 to convert the light into red and green light, thereby increasing the color conversion efficiency of the color conversion pattern 30, and alleviating the problem of emitting bluish light from the backlight.

The distributed Bragg reflector 140 is composed of a first film layer and a second film layer alternately arranged, the first film layer has a different refractive index from the second film layer, and the case where the first film layer has a higher refractive index than the second film layer is taken as an example. The refractive indexes of the first film layer and the second film layer determine a reflectivity of the distributed Bragg reflector 140. Specifically, the reflectivity of the distributed Bragg reflector 140 may be calculated by:

$$R = {( \frac{1 - \frac{{n}_{o}}{{n}_{i}} {( \frac{{n}_{H}}{{n}_{L}} )}^{2 N}}{1 + \frac{{n}_{o}}{{n}_{i}} {( \frac{{n}_{H}}{{n}_{L}} )}^{2 N}} )}^{2} ,$$

where N represents the number of dielectric layer pairs (where one first film layer and one second film layer adjacent thereto form one dielectric layer pair), n_{H} is a refractive index of the first film, n_{L} is a refractive index of the second film, nₒ is a refractive index of an incident medium, and nᵢ is a refractive index of an exiting medium. A bandwidth Δλ of a photonic band gap may be determined by:

$$Δ {λ}_{0} \frac{4 {λ}_{0}}{π} a sin ( \frac{{n}_{H} - {n}_{L}}{{n}_{H} + {n}_{L}} ) ,$$

where λ0 is a central wavelength of a wave band.

Accordingly, two exemplary distributed Bragg reflectors 140, each including five dielectric layer pairs, are given in the embodiments of the present disclosure, where one of the distributed Bragg reflectors 140 is composed of TiO₂ and ZnO alternately arranged, while the other is composed of ZnO and SiO₂ alternately arranged.

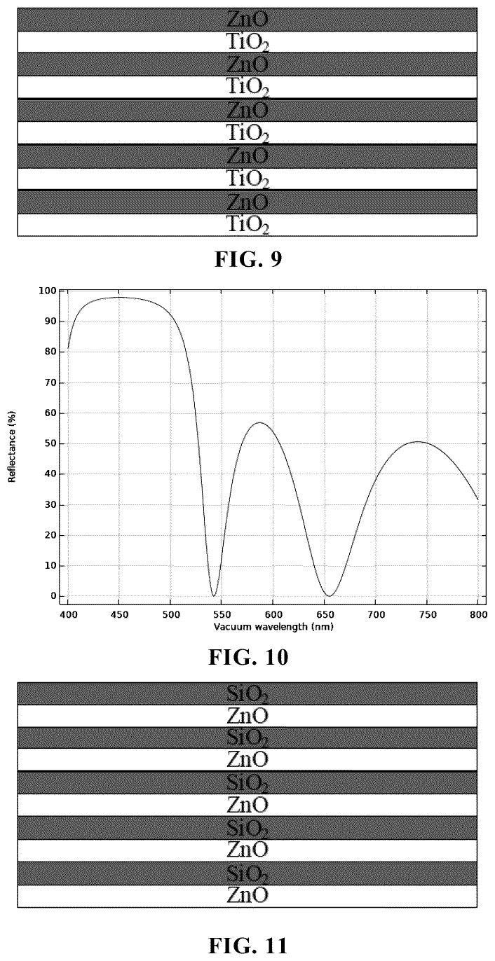

In one example, FIG. 9 is a sectional view of a distributed Bragg reflector 140 in the backlight structure in FIG. 8. As shown in FIG. 9, where the distributed Bragg reflector 140 is composed of TiO₂ and ZnO alternately arranged, each TiO₂ layer has a thickness of 44 nm, each ZnO layer has a thickness of 56 nm, and λ0 is 450 nm, it is calculated that the band width Δλ is about 70 nm based on the above calculation equation for the band width Δλ of the photonic band gap. A reflectivity vs. wavelength plot for this distributed Bragg reflector 140 structure is shown in FIG. 10, and it is known that a central wavelength of blue light is 450 nm, a central wavelength of green light is 535 nm, and a central wavelength of red light is 640. The central wavelength of blue light corresponds to a reflectivity of 98%, the central wavelength of green light corresponds to a reflectivity of 10%, and the central wavelength of red light corresponds to a reflectivity of 10%. As can be seen, the distributed Bragg reflector 140 of such a structure may have a higher reflectivity for blue light, and higher transmittances for red and green light.

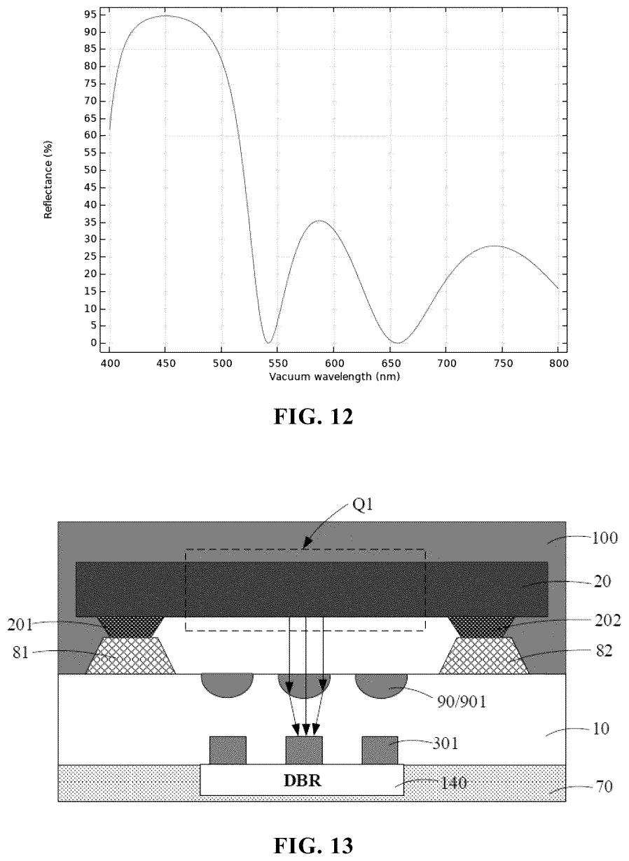

In another example, FIG. 11 is a sectional view of another distributed Bragg reflector 140 in the backlight structure in FIG. 8. As shown in FIG. 11, when the distributed Bragg reflector 140 is composed of ZnO and SiO₂ alternately arranged, each ZnO layer has a thickness of 75 nm, each SiO₂ layer has a thickness of 56 nm, and 20 is 450 nm, and it is calculated that the band width Δλ is about 90 nm based on the above calculation equation for the band width Δλ of the photonic band gap. A reflectivity vs. wavelength plot for this distributed Bragg reflector 140 structure is shown in FIG. 12, and it is known that a central wavelength of blue light is 450 nm, a central wavelength of green light is 535 nm, and a central wavelength of red light is 640 nm. The central wavelength of blue light corresponds to a reflectivity of 95%, the central wavelength of green light corresponds to a reflectivity of 5%, and the central wavelength of red light corresponds to a reflectivity of 5%. As can be seen, the distributed Bragg reflector 140 of such a structure may have a higher reflectivity for blue light, and higher transmittances for red and green light.

Only two specific structures of the distributed Bragg reflector 140 are given above, but it should be understood that the structure of the distributed Bragg reflector 140 is not limited to the above structures, and may be specifically designed according to specific requirements on the reflectivity.

In some examples, the distributed Bragg reflector 140 may be specifically disposed on a side of the dielectric substrate 10 away from the LED chip 20. This position can facilitate manufacturing of the product. Alternatively, it is feasible as long as the distributed Bragg reflector 140 is provided on the emission side of the color conversion layer.

Other structures in this example may be the same as those in the first example, and thus are not repeated here.

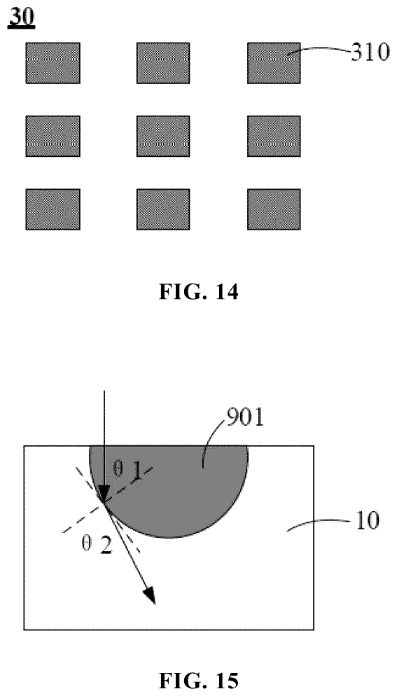

Sixth example: FIG. 13 is a sectional view of a sixth exemplary backlight structure according to an embodiment of the present disclosure; and FIG. 14 is a top view of a color conversion layer in the backlight structure in FIG. 13. As shown in FIGS. 13 and 14, the backlight structure includes a dielectric substrate 10, a plurality of LED chips 20, a color conversion layer, and a plurality of first microstructures 90. The color conversion layer includes a plurality of color conversion patterns 30, and the first microstructures 90 are located between the LED chips 20 and the color conversion patterns 30. Taking the color conversion patterns 30 made of a quantum dot material as an example, each of the color conversion patterns 30 includes a plurality of color conversion units 310 arranged at intervals, such as color conversion units 310 arranged in an array. The dielectric substrate 10 has a plurality of first grooves and a plurality of second grooves each in one-to-one correspondence with the LED chips 20. Each of the first grooves includes a plurality of first sub-grooves each receiving one of the color conversion units 310. A lens assembly 901 of each first microstructure 90 is disposed in one of the second grooves. Light emitted from each LED chip 20 is gathered by the lens assembly 901 and then impinges to a corresponding color conversion unit 310. In this example, by disposing the lens assembly 901, a color conversion material can be printed directly below the lens assembly 901, that is, the color conversion units 310 are formed, so that the color conversion units 310 are aligned, and the problem of a large emission area is solved.

Specifically, the dielectric substrate 10 has a first surface and a second surface disposed opposite to each other in a thickness direction thereof, and the first surface is closer to the LED chip 20 than the second surface. The first grooves are formed on the second surface side, and the second grooves are formed on the first surface side. One color conversion unit 310 is disposed in each first groove, and one lens assembly 901 is disposed in each second groove, where the lens assemblies 901 are arranged in one-to-one correspondence with the color conversion units 310 and have a certain distance from the LED chips. For a lens assembly 901 and a color conversion unit 310 in correspondence, light emitted from the corresponding LED chip 20 is gathered by the lens assembly 901 and then impinges to the color conversion unit 310. In this case, the lens assembly 901 should have a refractive index higher than the dielectric substrate 10. FIG. 15 is a schematic diagram showing refraction angles of light by a lens assembly 901 and a dielectric substrate 10 in the backlight structure in FIG. 13. As shown in FIG. 15, light emitted from the LED chip 20 and impinging to the lens assembly 901 has an incident angle θ1, and an exit angle θ2 from the lens assembly 901, where θ2>θ1, thereby implementing gathering of the light.

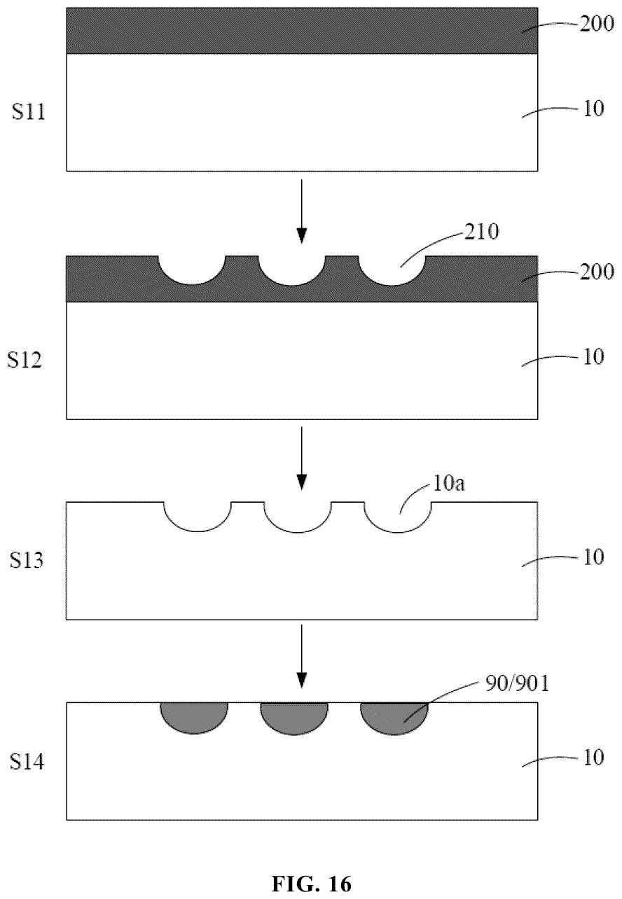

In some examples, FIG. 16 is a flowchart illustrating a process of forming a first microstructure 90 on the dielectric substrate 10 in the backlight structure in FIG. 13. As shown in FIG. 16, taking the dielectric substrate 10 being a glass substrate as an example, forming the first microstructure 90 on the glass substrate may include the following process steps S11 to S14.

At S11, coating nanoimprint glue 200 on a glass substrate.

At S12, processing the nanoimprint glue 200 by a nanoimprint technique, to obtain a first pattern 210 adapted to a second groove to be formed.

At S13, etching the glass substrate to form a pattern 10a including the second groove.

At S14, filling the second groove 10a with a lens material, and forming a lens assembly 901 in the second groove to form a first microstructure 90 (including a lens assembly 901).

In some examples, in addition to the above structures, the backlight structure further includes a distributed Bragg reflector 140 on a side of the color conversion pattern 30 away from the LED chip 20. The distributed Bragg reflector 140 may have the same structure as in the fifth example, and thus is not repeated here. Blue light is highly reflected by the distributed Bragg reflector 140 so that the reflected blue light can further excite the color conversion pattern 30 to convert the light into red and green light, thereby increasing the color conversion efficiency of the color conversion pattern 30, and alleviating the problem of emitting bluish light from the backlight.

Further, a package layer 70 is provided on a side of the distributed Bragg reflector 140 away from the dielectric substrate 10, and covers at least the color conversion layer, thereby preventing erosion of water and oxygen. Specifically, the package layer 70 may have a planar structure which can better seal the structures on the dielectric substrate 10.

In some examples, in addition to the above structures, the backlight structure in the embodiments of the present disclosure may further include a scattering layer 40 on a side of the color conversion pattern 30 away from the LED chip 20. The scattering layer 40 may be disposed between the distributed Bragg reflector 140 and the color conversion pattern 30, and configured to scatter light emitted from the LED chip 20 and converted through the color conversion pattern 30, as well as light transmitted through the color conversion pattern 30.

Further, with continued reference to FIG. 13, the dielectric substrate 10 has a first surface facing the LED chip 20; and in addition to the above structures, the backlight structure further includes: a second microstructure 50 and a light-shielding layer 60 on the first surface and sequentially arranged in a direction approaching the LED chip 20. The second microstructure 50 is configured to diffuse the light emitted from the color conversion layer; and the backlight structure includes a first opening running through the second microstructure 50 and the light-shielding layer 60, through which light emitted from the LED chip 20 impinges onto the color conversion pattern 30. For example: the first opening is disposed in one-to-one correspondence with the LED chip 20, and in this case, light scattered by the scattering layer 40 impinges onto the second microstructure 50 and then is further diffused, so that the light is more uniform, and by providing the light-shielding layer 60, light leakage can be effectively prevented.

Further, the second microstructure 50 may specifically adopt a lens structure, which is equivalent to a diffusion plate. The light-shielding layer 60 may be made of a black resin material or a light-shielding metal material, which is not particularly limited in the embodiments of the present disclosure.

In some examples, with continued reference to FIG. 13, the LED chip 20 is a flip chip, i.e., the first connection pad 201 and the second connection pad 202 of the LED chip 20 are arranged towards the dielectric substrate 10 side. Accordingly, the backlight structure further includes a first lead terminal 81 and a second lead terminal 82 on the dielectric substrate 10 and at two opposite sides of the first groove. The first connection pad 201 of the LED chip 20 is connected to the first lead terminal 81, and the second connection pad 202 of the LED chip 20 is connected to the second lead terminal 82. Specifically, the first connection pad 201 and the first lead terminal 81 may be connected by soldering, and similarly, the second connection pad 202 and the second lead terminal 82 may also be connected by soldering.

Alternatively, the LED chip 20 may be a face up chip, that is, the first connection pad 201 and the second connection pad 202 of the LED chip 20 are disposed away from the dielectric substrate 10. Accordingly, the first connection pad 201 may be connected to the first lead terminal 81 on the dielectric substrate 10 through a first signal line 101, and the second connection pad 202 may be connected to the second lead terminal 82 on the dielectric substrate 10 through a second signal line 102. The face up LED chip 20 can further reduce a distance between the emission surface of the LED chip 20 and the color conversion pattern 30, reduce a transmission distance of the light emitted from the LED chip 20 in the air medium, and increase the utilization rate of the light. The LED chips 20 may be connected in a manner the same as that in the second example, which is not repeated here.

In some examples, with continued reference to FIG. 13, the side of the LED chip 20 away from the dielectric substrate 10 is covered with a second reflective layer 100, to cause light emitted from the LED chip 20 to exit towards the dielectric substrate 10. In some examples, the second reflective layer 100 includes, but is not limited to, white oil.

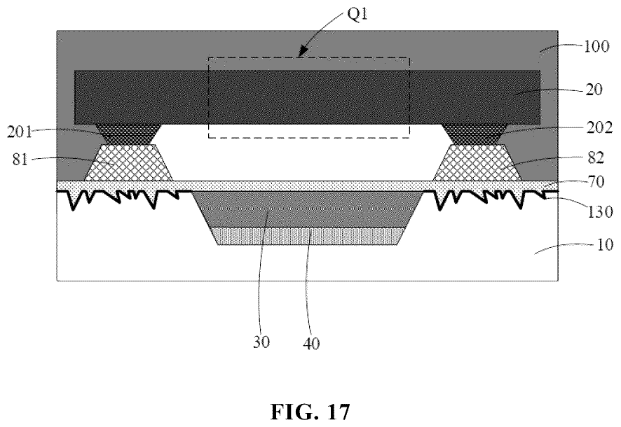

Seventh example: FIG. 17 is a sectional view of a seventh exemplary backlight structure according to an embodiment of the present disclosure. As shown in FIG. 17, this backlight structure is substantially the same as that of the first example, except that the second microstructure 50 and the light-shielding layer 60 are not provided in the backlight structure. Instead, a first surface of the dielectric substrate 10 is roughened, and a first reflective layer 130 is formed on the roughened first surface, to realize the same functions of the second microstructure 50 and the light-shielding layer 60. Specifically, the dielectric substrate 10 has a first surface facing the light-emitting chip and having a flat region and a groove region; a first groove is located in the groove region; the flat region of the first surface is a rough surface provided with a first reflective layer 130 on a side close to the light-emitting chip. In this case, the light emitted through the color conversion pattern 30 is further scattered after impinging to the rough surface, and reflected and emitted through the first reflective layer 130, so that the emitted light is more uniform.

In some examples, a material of the first reflective layer 130 includes, but is not limited to, Ag.

It should be noted that in the second to fifth examples, the second microstructure 50 and the light-shielding layer 60 may be replaced by the rough surface and the first reflective layer 130, and these structures are also within the protection scope of the embodiments of the present disclosure.

An embodiment of the present disclosure provides a display apparatus, which may include any of the above backlight structures. Alternatively, it may further include a display panel on an emission surface side of the backlight structure.

The display apparatus may be: a mobile phone, a tablet, a television, a monitor, a laptop, a digital album, a navigator or any other product or component having a display function, but the embodiments of the present disclosure are not limited thereto.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A light-emitting substrate, comprising:
a dielectric substrate having a plurality of first grooves;
a plurality of light-emitting chips on the dielectric substrate; and
a color conversion layer comprising a plurality of color conversion patterns on an emission side of the light-emitting chips; wherein at least one of the color conversion patterns is in the first grooves.

2. The light-emitting substrate according to claim 1, further comprising a first microstructure between the light-emitting chips and the color conversion patterns, wherein a certain distance is provided between the first microstructure and the dielectric substrate, and the first microstructure is configured to gather light emitted from the light-emitting chips and transmit the gathered light to the color conversion patterns.

3. The light-emitting substrate according to claim 1, further comprising a first microstructure on the dielectric substrate and on a side of the color conversion patterns close to the light-emitting chips, wherein a certain distance is provided between the first microstructure and the light-emitting chips, and the first microstructure is configured to gather light emitted from the light-emitting chips and transmit the gathered light to the color conversion patterns.

4. The light-emitting substrate according to claim 3, wherein the dielectric substrate has a plurality of second grooves, each of which is provided with one lens assembly of the first microstructure.

5. The light-emitting substrate according to claim 3, wherein each of the color conversion patterns comprises a plurality of color conversion units arranged at intervals; each of the first grooves comprises a plurality of first sub-grooves arranged at intervals and each provided with one of the color conversion units; and lens assemblies of each of the first microstructures are in one-to-one correspondence with the color conversion units.

6. The light-emitting substrate according to claim 1, wherein each of the color conversion patterns comprises a plurality of color conversion sublayers and a plurality of transparent film layers alternately arranged in a stack; and light emitted from the light-emitting chips is transmitted and reflected at interfaces of the color conversion sublayers and the transparent film layers.

7. The light-emitting substrate according to claim 1, further comprising a transflective film layer on a side of the color conversion patterns away from the light-emitting chips, wherein the transflective film layer is configured to transmit a part and reflect another part of light emitted from the light-emitting chips.

8. The light-emitting substrate according to claim 1, wherein the light-emitting chips are configured to emit light of a first color which excites the color conversion layer to emit light of a second color and light of a third color; the light-emitting substrate further comprises a distributed Bragg reflector on a side of the color conversion layer away from the light-emitting chips; the distributed Bragg reflector has a reflectivity to the light of the second color and a reflectivity to the light of the third color each lower than a reflectivity to the light of the first color; and the distributed Bragg reflector has a transmittance to the light of the second color and a transmittance to the light of the third color each higher than a transmittance to the light of the first color.

9. The light-emitting substrate according to claim 8, wherein the distributed Bragg reflector comprises titanium dioxide film layers and zinc oxide film layers sequentially and alternately arranged in a direction away from the color conversion patterns; or, the distributed Bragg reflector comprises zinc oxide film layers and silicon dioxide film layers sequentially and alternately arranged in a direction away from the color conversion patterns.

10. The light-emitting substrate according to claim 1, wherein the dielectric substrate has a first surface facing the light-emitting chips and having a flat region and a groove region; the first grooves are in the groove region; the flat region of the first surface is a rough surface provided with a first reflective layer on a side close to the light-emitting chips.

11. The light-emitting substrate according to claim 1, wherein the dielectric substrate has a first surface facing the light-emitting chips; the light-emitting substrate further comprises: a second microstructure and a light-shielding layer on the first surface and sequentially arranged in a direction approaching the light-emitting chips; the second microstructure is configured to diffuse light emitted from the color conversion layer; and the light-emitting substrate further comprises a plurality of first openings running through the second microstructure and the light-shielding layer, and light emitted from the light-emitting chips impinges onto the color conversion patterns through the first openings.

12. The light-emitting substrate according to claim 1, wherein in a plane where the dielectric substrate is located, an orthographic projection of each of the first grooves covers an orthographic projection of one of the first openings.

13. The light-emitting substrate according to claim 1, further comprising a first lead terminal and a second lead terminal on the dielectric substrate and at two opposite sides of each of the first grooves; wherein a first connection pad of each of the light-emitting chips is connected to the first lead terminal, and a second connection pad of each of the light-emitting chips is connected to the second lead terminal.

14. The light-emitting substrate according to claim 13, wherein the first connection pad is disposed toward, and directly connected to, the first lead terminal; and the second connection pad is disposed toward, and directly connected to, the second lead terminal.

15. The light-emitting substrate according to claim 13, wherein the first connection pad is disposed away from the first lead terminal, and connected to the first lead terminal by a first signal line; and the second connection pad is disposed away from the second lead terminal, and connected to the second lead terminal by a second signal line.

16. The light-emitting substrate according to claim 1, further comprising a scattering layer on a side of the color conversion patterns away from the light-emitting chips.

17. The light-emitting substrate according to claim 1, further comprising a package layer that covers the color conversion layer.

18. The light-emitting substrate according to claim 1, further comprising a second reflective layer on a side of the light-emitting chips away from the dielectric substrate.

19. The light-emitting substrate according to claim 1, wherein the color conversion layer is made of a material comprising quantum dots or phosphors.

20. A display apparatus, comprising the light-emitting substrate according to claim 1.
